(19) United States
(12) Patent Application Publication
(10) Pub. No.: US 2007/0259483 A1
(43) Pub. Date: Nov. 8, 2007

(54) Sawing Apparatus and a Control Method for Manufacturing Processes of Semiconductor Package

(75) Inventor: Yong-Goo Lee, Incheon (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hanmi Semiconductor Co., Ltd., Incheon (KR)

(21) Appl. No.: 11/574,392

(22) PCT Filed: Aug. 31, 2004
(86) PCT No.: PCT/KR04/02189

§ 371 Date: Feb. 27, 2007

(51) Int. Cl. H01L 21/78

(52) U.S. Cl. 438/113

(57) ABSTRACT

Disclosed is a sawing apparatus for manufacturing a semiconductor package, capable of simultaneously performing strip loading work and package unloading work during the sawing process to improve productivity of the semiconductor packages. The sawing apparatus includes a chuck table base 200; a chuck table 23 installed on the chuck table base 200 such that the chuck table 23 horizontally moves on the chuck table base 200; two chuck plates 233a and 233b rotatably installed on the chuck table 23 such that a strip S is loaded on upper surfaces of the chuck plates 233a and 233b by turns; a sawing machine 30 for dividing the strip S loaded on the chuck plate into individual packages P by performing a relative movement with respect to the chuck table 23; and a strip/package picker 22 for loading the strip S onto the chuck plates and unloading the packages P from the chuck plates,

### TECHNICAL FIELD

The present invention relates to a sawing apparatus and a control method thereof for manufacturing semiconductor packages. More particularly, the present invention relates to a sawing apparatus and a control method thereof capable of improving productivity of semiconductor packages by improving the structure of a chuck table and the sawing process.

### BACKGROUND ART

In general, a semiconductor package is obtained through various fabrication processes of forming a semiconductor chip having highly integrated circuits, such as transistors and capacitors, on a silicon semiconductor substrate, attaching the silicon semiconductor substrate to a lead frame or a printed circuit board, electrically connecting the semiconductor chip to the lead frame or the printed circuit using a wire, and molding EMC (epoxy molding compound) onto the semiconductor chip such that the semiconductor chip can be protected from external environment.

Such a semiconductor package is generally packaged into the lead frame in a matrix pattern, so that a sawing process is performed in order to divide the semiconductor package provided in the lead frame or the printed circuit board into individual packages. After the sawing process has been completed, the individual packages are stacked on trays according to quality thereof and then moved into the next stage.

In general, the lead frame or the printed circuit board is fabricated in the form of a rectangular strip, so they are called “strips”. The strip is sawn in transverse and longitudinal directions thereof, thereby forming a package.

An apparatus used for the sawing process is disclosed in Korean Patent Application No. 10-2000-0079282 (Unexamined Publication No. 2002-0049954) entitled “Handler system for cutting a semiconductor package device”, which has been filed by applicant of the present invention.

As shown in FIG. 1, the conventional sawing and handler system includes a strip/package picker 22 horizontally moving along a guide rail 24 in order to pick up the introduced strip and load the strip onto a chuck table 23 or unload packages from the chuck table 23. The chuck table 23 is installed on a chuck table base 200 so as to horizontally move or rotate the strip loaded on the chuck table 23 by the strip/package picker 22. The conventional sawing and handler system also includes a sawing machine 30 for dividing the strip into several individual packages when the strip is transferred thereto by means of the chuck table 23, a cleaning unit 40 for removing impurities generated when the sawing process is performed by means of the sawing machine 30 and a drying unit 50 for drying the packages after the cleaning process has been finished. The above elements of the conventional handler system are disclosed in the Korean Patent Application No. 10-2000-0079282 in detail, so they will not be further described below if they do not relate to the present invention.

FIG. 2 is a view illustrating the relationship between the strip/package picker and the chuck table shown in FIG. 1.

As shown in FIG. 2, a chuck plate 233 is mounted on an upper surface of the chuck table 23 and the strip/package picker 22 includes a strip picker head 221 and a package picker head 222, which are movably installed above the chuck plate 233. A pickup unit 231 is provided at an upper portion of the chuck plate 233 in order to pick up the strip or the package by using a vacuum.

Herein, “P” is packages fixed to the chuck plate 233 after strip is sawn by means of the sawing machine 30, and “S” is a strip to be loaded on the chuck plate 233 while being picked up by means of the strip picker head 221.

Hereinafter, the sawing process in the conventional handler system having the above structure will be briefly described. First, when the strip S is introduced into the system from an on-loader unit 10 through a pusher 12, the strip picker head 221 of the strip/package picker 22 picks up the strip S and moves along the guide rail 24 to load the strip S onto the chuck plate 233.

Then, the strip S is fixed to the chuck plate 233 due to vacuum force and transferred to the sawing machine 30. Thus, the strip S is sawn into individual packages P caused by the relative movement between the chuck table 23 and the sawing machine 30.

In the meantime, while the strip S aligned on the chuck table 23 is being sawn due to the relative movement between the chuck table 23 and the sawing machine 30, the strip picker head 221 of the strip/package picker 22 moves toward the on-loader unit 10 to pick up a new strip introduced into the system. Then, the strip picker head 221 of the strip/package picker 22 moves back toward a strip unloading position and maintains a standby state such that the new strip S can be loaded on the chuck plate 233.

After the strip S has been sawn into individual packages by means of the sawing machine 30, the individual packages P are transferred to their initial positions by means of the chuck table 23 and loaded on the package picker head 222. Then, the strip picker head 221 of the strip/package picker 22 standing by in the strip unloading position loads the new strip on the chuck plate 233, thereby completing the sawing process.

When the sawing process has been finished, the conventional handler system sequentially transfers the packages P loaded on the package picker head 222 to the cleaning unit 40 and the drying unit 50, thereby cleaning and drying the packages P.

However, according to the conventional handler system, only one chuck plate 233 is mounted on the chuck table 23, so that the new strip S picked up by the strip picker head 221 must be loaded on the chuck plate 233 after the individual packages P loaded on the chuck plate 233 have been unloaded onto the package picker head 222. That is, according to the prior art, the chuck plate 233 must be maintained in an empty state in order to load the new strip S picked up by the strip picker head 221 onto the chuck plate 233. For this reason, the individual packages P loaded on the chuck plate 233 through the sawing process must be removed from the chuck plate 233 before the new strip S is loaded onto the chuck plate 233.

Accordingly, when the sawing process is performed by means of the conventional handler system, unloading work for the package and loading work for the strip may not be simultaneously performed. That is, the unloading work for the package and the loading work for the strip may be sequentially performed so that the unloading of the package and the loading of the strip may not be rapidly performed, thereby increasing working time.

### DISCLOSURE OF THE INVENTION

Therefore, the present invention has been made in view of the above-mentioned problems, and it is an object of the present invention to provide a sawing apparatus and a control method thereof capable of improving productivity of semiconductor packages by performing unloading work for the semiconductor packages simultaneously with loading work for the strip during the sawing process.

In order to accomplish the above object, according to one aspect of the present invention, there is provided a sawing apparatus for manufacturing a semiconductor package, the sawing apparatus comprising: a chuck table base; a chuck table installed on the chuck table base such that the chuck table horizontally moves on the chuck table base; two chuck plates rotatably installed on the chuck table such that a strip is loaded on upper surfaces of the chuck plates by turns; a sawing machine for dividing the strip loaded on the chuck plate into individual packages by performing a relative movement with respect to the chuck table; and a strip/package picker for loading the strip onto the chuck plates and unloading the packages from the chuck plates, simultaneously.

According to the preferred embodiment of the present invention, the strip/package picker includes a strip picker for loading the strip onto the chuck plate while moving in an X-axis direction and a package picker for unloading the packages from the chuck plate while moving in the X-axis direction in parallel to the strip picker when the strip picker loads the strip onto the chuck plate.

According to another aspect of the present invention, there is provided a method of controlling a sawing apparatus for manufacturing a semiconductor package and including two chuck plates, the method comprising the steps of: i) loading a strip on a first chuck plate of two chuck plates; ii) aligning the strip loaded on the first chuck plate; iii) sawing the strip loaded on the first chuck plate into individual packages; and iv) unloading the packages by rotating the first chuck plate from an initial position thereof by an angle of 180° and loading a new strip onto a second chuck plate of two chuck plates, simultaneously.

### BRIEF DESCRIPTION OF THE DRAWINGS

The foregoing and other objects, features and advantages of the present invention will become more apparent from the following detailed description when taken in conjunction with the accompanying drawings in which:

FIG. 1 is a plan view illustrating a conventional handler system for cutting a semiconductor package device;

FIG. 2 is a view illustrating the relationship between a strip/package picker and a chuck table shown in FIG. 1;

FIG. 3 is a plan view illustrating a sawing apparatus for manufacturing a semiconductor package according to a first embodiment of the present invention;

FIG. 4 is a perspective view illustrating a chuck table and a chuck plate shown in FIG. 3;

FIG. 5 is a plan view illustrating a strip/package picker shown in FIG. 3;

FIG. 6 is a view illustrating the relationship between strip/package picker heads and two chuck tables shown in FIG. 3;

FIGS. 7a and 7b are views illustrating a control procedure for a sawing apparatus for manufacturing a semiconductor package according to a first embodiment of the present invention;

FIGS. 8a and 8b are views illustrating another control procedure for a sawing apparatus for manufacturing a semiconductor package according to a first embodiment of the present invention;

FIGS. 9a and 9b are views illustrating still another control procedure for a sawing apparatus for manufacturing a semiconductor package according to a first embodiment of the present invention;

FIG. 10 is a view illustrating still yet another control procedure for a sawing apparatus for manufacturing a semiconductor package according to a first embodiment of the present invention;

FIG. 11 is a plan view illustrating a sawing apparatus for manufacturing a semiconductor package according to a second embodiment of the present invention;

FIGS. 12a and 12b are views illustrating a control procedure for a sawing apparatus for manufacturing a semiconductor package according to a second embodiment of the present invention;

FIGS. 13a and 13b are views illustrating another control procedure for a sawing apparatus for manufacturing a semiconductor package according to a second embodiment of the present invention;

FIGS. 14a and 14b are views illustrating still another control procedure for a sawing apparatus for manufacturing a semiconductor package according to a second embodiment of the present invention; and

FIG. 15 is a view illustrating still yet another control procedure for a sawing apparatus for manufacturing a semiconductor package according to a first embodiment of the present invention.

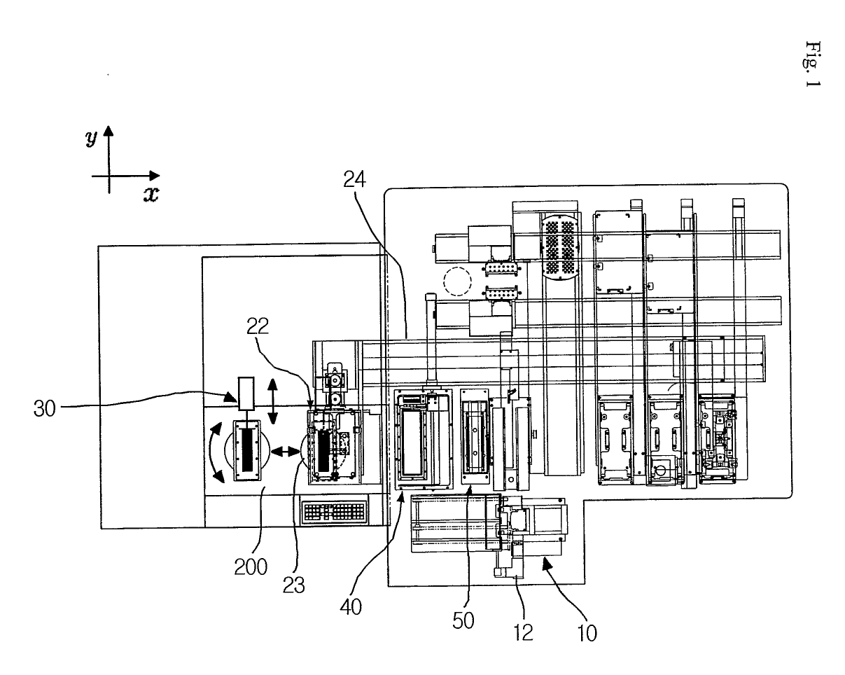

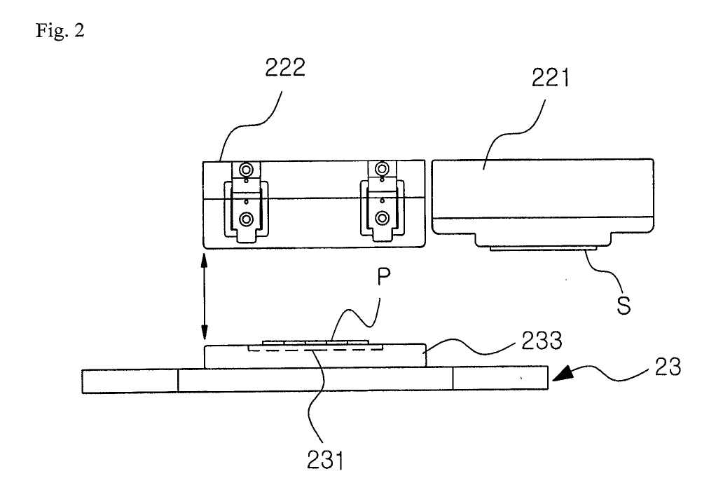

### BEST MODE FOR CARRYING OUT THE INVENTION

Hereinafter, a first embodiment of the present invention will be described with reference to accompanying drawings.

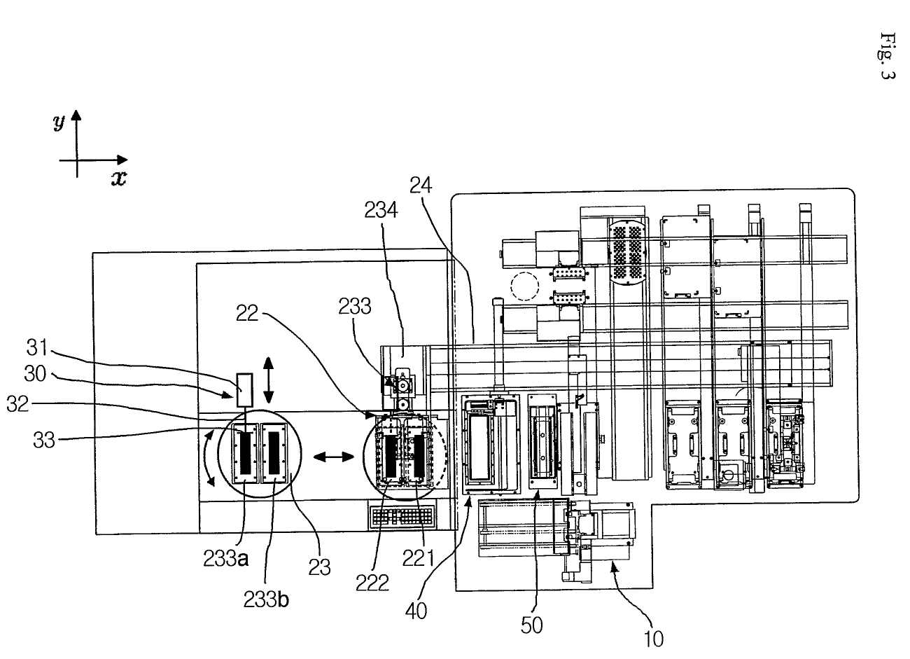

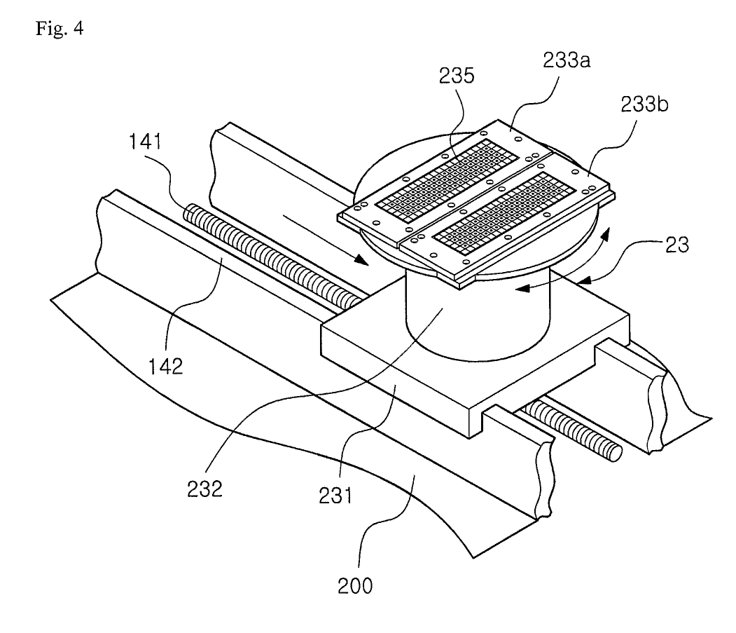

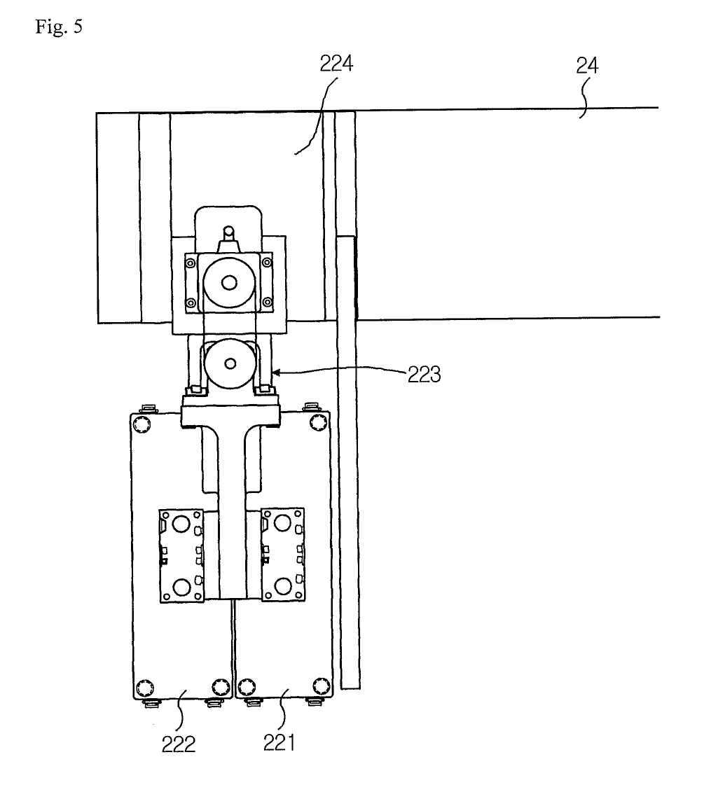

FIG. 3 is a plan view illustrating a sawing apparatus for manufacturing a semiconductor package according to a first embodiment of the present invention, FIG. 4 is a perspective view illustrating a chuck table and a chuck plate shown in FIG. 3, and FIG. 5 is a plan view illustrating a strip/package picker shown in FIG. 3.

As shown in FIGS. 3 to 5, the sawing apparatus according to the present invention includes a chuck table 23 installed on a chuck table base 200 such that the chuck table can horizontally move in an X-axis direction on the chuck table base 200 and two chuck plates 233a and 233b rotatably installed on the chuck table 23 such that a strip S is alternately loaded on the chuck plates 233a and 233b.

As shown in FIG. 4, the chuck table 23 includes a base plate 231 and a servo motor 232 provided on an upper surface of the base plate 231. Here, the base plate 231 is installed on a guide rail 142 mounted on the chuck table base 200 and a lower portion of the base plate 231 is screw-coupled with a ball screw 141 so that the base plate 231 is horizontally moved as the ball screw 141 rotates.

In addition, the chuck plates 233a and 233b are provided on an upper part of the servo motor 232 so that the chuck plates 233a and 233b may rotate as the servo motor 232 is driven.

The strip S is alternately loaded on upper surfaces of the chuck plates 233a and 233b. That is, the strip S to be sawn is loaded on the chuck plates 233a and 233b by turns.

To this end, the strip/package picker 22 may rotate at an angle of 180° so as to alternately load the strip S on the upper surfaces of the chuck plates 233a and 233b. However, according to the preferred embodiment of the present invention, the chuck plates 233a and 233b may rotate at an angle of 180° in order to alternately receive the strip S from the strip/package picker 22 and unload the packages P.

The strip S loaded on the chuck plate 233a or 233b is securely fixed to the chuck plate 233a or 233b due to suction force applied thereto through a suction hole 235. In order to provide the suction force through the suction hole 235, the chuck table 23 is equipped with a well-known air suction unit (not shown).

According to the present invention, a sawing machine 30 is provided to divide the strip S loaded on the chuck plate into individual packages P. As shown in FIG. 3, the sawing machine 30 includes a motor 31, which can horizontally move in a Y-axis direction and vertically move in perpendicular to the chuck plate, a spindle 32 rotatably coupled to the motor 31, and a sawing blade 33 rotatably mounted on an end portion of the spindle 32 so as to divide the strip S into individual packages P.

The sawing machine 30 having the above structure may cut the strip S in transverse and longitudinal directions thereof according to the relative movement between the sawing machine 30 and the chuck table 23. At this time, in order to prevent the chuck plate having no strip S from being contaminated, the rotational direction of the sawing blade 33 is controlled such that chips generated during the sawing process are prevented from moving toward the chuck plate having no strip S.

That is, the sawing machine 30 divides the strip S loaded on the chuck table into individual packages P by using the sawing blade 33 while horizontally moving in the Y-axis direction and vertically moving in perpendicular to the ground. At this time, the chuck table 23 rotates the strip S at an angle of 90° while horizontally moving the strip S in an X-axis direction, so that the strip S is sawn in transverse and longitudinal directions thereof.

In the meantime, although it is illustrated that the sawing machine 30 of the present invention divides the strip S into individual packages P while horizontally moving in the Y-axis direction, it is also possible to cut the strip S in the transverse and longitudinal directions thereof by rotating the sawing blade 33 while horizontally moving and rotating the chuck table 23 in the Y-axis direction in a state in which the sawing machine 30 is fixedly maintained.

In addition, although it is illustrated that the sawing machine 30 of the present invention is equipped with only one sawing blade, the sawing machine 30 can be equipped with a pair of sawing blades 33 symmetrically aligned in the Y-axis direction. The sawing machine 30 may perform the sawing process by using laser, water, etc.

The present invention includes the strip/package picker 22 for simultaneously loading the strip S onto the chuck plates 233a and 233b and unloading the packages P from the chuck plates 233a and 233b.

As shown in FIG. 5, the strip/package picker 22 includes a strip picker head 221 for loading the strip S onto the chuck plate, a package picker head 222 for unloading the packages P from the chuck plate, a picker head lifting unit 223 for moving the strip picker head 221 and the package picker head 222 up and down, a transfer unit 224 for horizontally reciprocating the strip picker head 221 and the package picker head 222 along the guide rail 24, a suction unit installed on lower surfaces of the strip picker head 221 and the package picker head 222 in order to pick up the strip S and the package P, respectively, and a vacuum port (not shown) for applying a vacuum to the suction unit.

In the strip/package picker 22 having the above structure, the strip picker head 221 loads the strip S onto the chuck plate and the package picker head 222 unloads the package P from the chuck plate, respectively.

Since the strip picker head 221 and the package picker head 222 perform strip loading work and package unloading work with respect to the chuck plate, respectively, the strip picker head 221 always maintains a clean state without being influenced by impurities or cooling water sticking to the package P when the strip S is sawn.

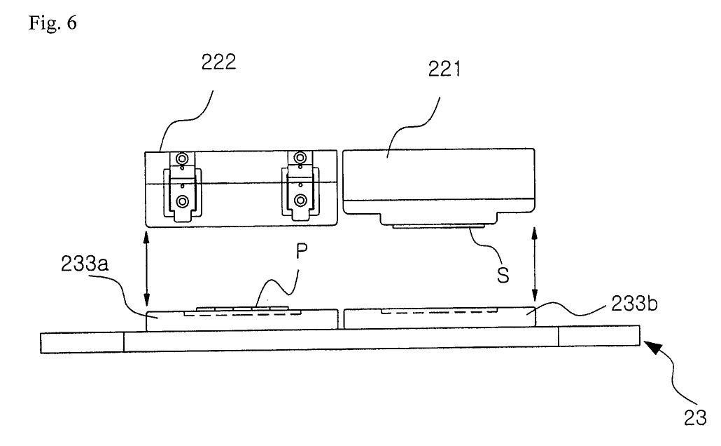

FIG. 6 is a view illustrating the relationship between strip/package picker heads 221 and 222 and two chuck tables 233a and 233b shown in FIG. 3.

As shown in FIG. 6, above two chuck plates 233a and 233b, the strip picker head 221 and the package picker head 222 simultaneously move down toward the chuck plates 233a and 233b such that the package picker head 222 unloads the packages P from the chuck plate 233a and the strip picker head 221 loads the strip S onto the chuck plate 233b, respectively.

Hereinafter, a method for controlling the sawing apparatus having the above structure for manufacturing the semiconductor package according to the first embodiment of the present invention will be described with reference to accompanying drawings.

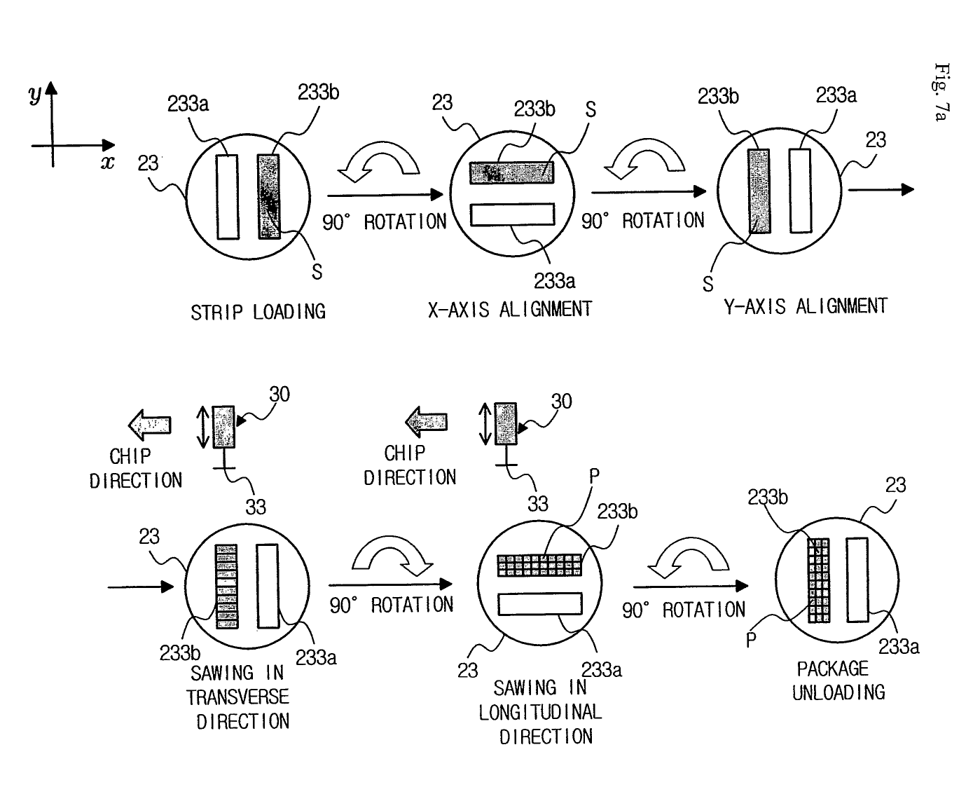

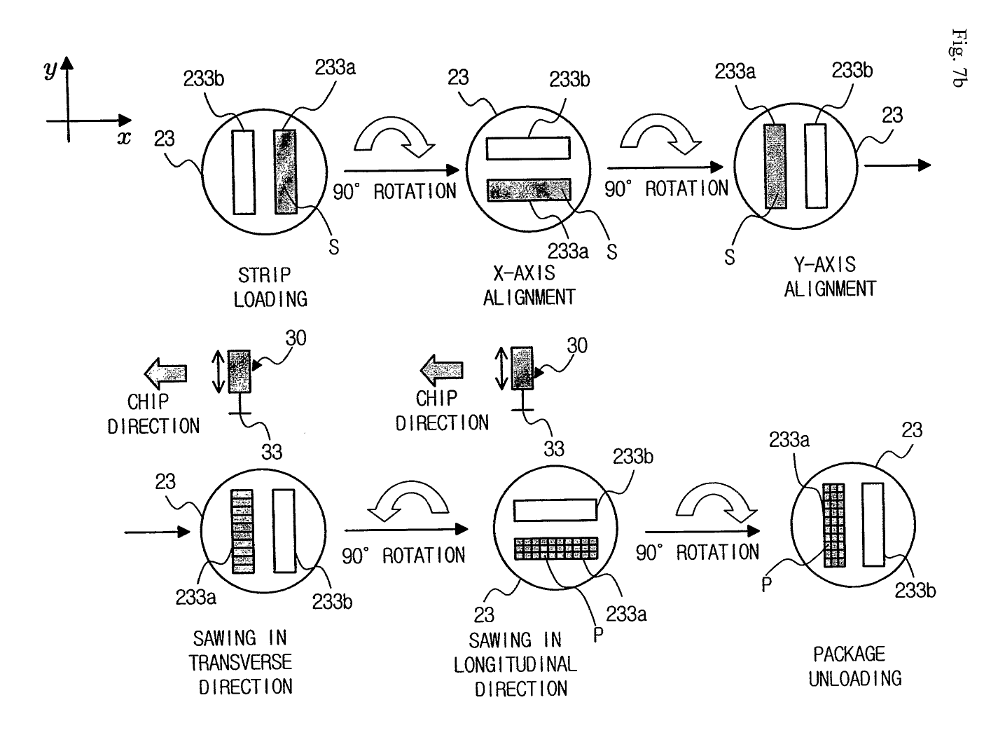

FIGS. 7a and 7b are views illustrating a control procedure for the sawing apparatus for manufacturing the semiconductor package according to the first embodiment of the present invention.

In FIGS. 7a and 7b, the chuck plate with a shadow signifies the chuck plate having the strip S loaded thereon, and the chuck plate with a check pattern signifies the chuck plate having the package P loaded thereon.

The method of controlling the sawing apparatus for manufacturing the semiconductor package according to the present invention mainly includes the steps of loading the strip S, aligning the strip S, sawing the strip S and unloading the packages. While the above steps are being carried out, the chuck table is rotated in a predetermined direction by a predetermined angle. The rotational direction and rotating angle of the chuck plates 233a and 233b may be variously selected if the chuck plates 233a and 233b can be maintained in a predetermined position rotated from the initial position (strip loading position) by an angle of 180° when the package P is unloaded from the chuck plate after the sawing process has been finished.

First, the method of controlling the sawing apparatus according to the first embodiment of the present invention will be described with reference to FIG. 7a.

The strip S is loaded on the chuck plate 233b, which is positioned on the right side of the chuck plate 233a. To this end, the strip picker head 221 picks up the strip S introduced into the sawing apparatus and moves down when the chuck plate 233b has been horizontally moved below the strip picker head 221 by means of the chuck table 23 so as to load the strip S onto the chuck plate 233b positioned on the right side of the chuck table 233a.

Then, the X and Y-axis alignment is performed with respect to the strip S loaded on the chuck plate 233b. To this end, the strip S loaded on the chuck plate 233b is photographed by means of a vision inspection device and then the chuck table 23 rotates two times in the counterclockwise direction by an angle of 90° per one rotation such that the X and Y-axis alignment can be performed with respect to the strip S. According to the first embodiment of the present invention, the vision inspection device is attached to the sawing machine. However, it is also possible to align the vision inspection device between the chuck table and the sawing machine. The X and Y-axis alignment is necessary to precisely cut the strip S loaded on the chuck plate 233b. After photographing the strip S, the vision inspection unit sends position information of the strip S to a controller, so that the controller controls the operation of the chuck table 23 and/or the sawing blade 33 to perform sawing work for the strip S. It is preferred to control the rotational direction and rotating angle of the chuck table 23 within an angle of 180° when aligning the strip S.

After that, the strip S aligned on the chuck plate 233b is sawn into individual packages P. First, the strip S is sawn in the transverse direction along the length thereof at regular intervals and then the strip S is sawn in the longitudinal direction along the width thereof at regular intervals by rotating the strip S in the clockwise direction.

In detail, the sawing blade 33 of the sawing machine 30 being rotated above the strip S moves down toward the strip S and the chuck plate 233b having the strip S loaded thereon is horizontally moved in the X-axis direction by means of the chuck table 23 so that the strip S is sawn in the transverse and longitudinal directions thereof.

At this time, the sawing machine 30 moves from a front portion to a rear portion of the strip S in the Y-axis direction with a predetermined time interval, thereby sawing the strip S at regular intervals.

Preferably, cooling water or cold air is sprayed onto the sawing blade 33 during the sawing process in order to prevent the sawing blade 33 of the sawing machine from being overheated.

In addition, in order to prevent the chuck plate 23 3a having no strip S loaded thereon from being contaminated by chips generated during the sawing process, the chips are preferably guided into a predetermined direction (chip direction shown in FIG. 7a) other than the direction toward the chuck plate 233a.

That is, the chuck plate 233b having the strip S loaded thereon is positioned on the left side or the upper side of the chuck plate 233a having no strip S loaded thereon, and the sawing blade 33 of the sawing machine 30 for sawing the strip S is rotated in the clockwise direction when viewed in the Y-axis direction, thereby allowing the chips generated during the sawing process for the strip S to be guided in the left direction in FIG. 7a.

It is preferable that chips generated during the sawing process are guided in the left direction in FIG. 7a, considering that the cleaning unit 40 can be prevented from being contaminated by the chips.

Accordingly, cooling water sprayed onto the sawing blade 33 of the sawing machine 30 is guided into the chip direction together with the chips generated during the sawing process without being directed toward the chuck plate 233a having no strip S loaded thereon, thereby preventing the chuck plate 233a from being contaminated.

After the sawing process has been finished, the packages P are rotated in the counterclockwise direction by an angle of 90° and then horizontally moved into the package unloading position. Thus, the individual packages P are unloaded from the chuck plate 233b and a new strip S is loaded onto the chuck plate 233a, simultaneously.

At this time, the chuck plate 233b is maintained in a position rotated from the initial position of the chuck plate by an angle of 180°, so that the packages P can be unloaded from the chuck plate 233b and the new strip S can be loaded on the chuck plate 233a, simultaneously. That is, the packages P are located below the package picker head 222 and the chuck plate 233a having no strip S loaded thereon is located below the strip picker head 221. In addition, the package picker head 222 and the strip picker head 221 simultaneously move down, so that the package picker head 222 unloads the packages P from the chuck plate 233b and the strip picker head 221 loads the new strip S onto the chuck plate 233a, simultaneously.

After that, the sawing process is again performed with respect to the new strip S loaded on the chuck plate 233a. At this time, the rotational direction of the strip S shown in FIG. 7a is reversed during the sawing process in order to prevent cables or vacuum lines from being entangled. That is, the strip S is rotated from the initial position in the forward or reverse direction within an angle of 180° when the sawing process is performed. Such a sawing process is shown in FIG. 7b.

Hereinafter, the method of controlling the sawing apparatus according to the first embodiment of the present invention will be described with reference to FIG. 7b.

Referring to FIG. 7b, the strip S is loaded on the chuck plate 233a other than the chuck plate 233b on which the strip S is loaded in FIG. 7a. That is, the strip S is alternately loaded on upper surfaces of the chuck plates 233a and 233b.

The control procedure shown in FIG. 7b is substantially similar to the control procedure shown in FIG. 7a except for the rotational direction of the strip S. Thus, detailed description thereof will be omitted below.

Since the rotational direction of the strip S shown in FIG. 7b is reversed with respect to the rotational direction of the strip S shown in FIG. 7a, the rotating angle of the chuck plates 233a and 233b is limited within an angle of 180°. Thus, the tangling of cables or vacuum lines, which may occur when the chuck plates 233a and 233b excessively rotate above an angle of 180°, can be prevented.

If there is no problem derived from the tangling of the cables or vacuum lines, it is not necessary to limit the rotating angle of the chuck plates 233a and 233b within an angle of 180°. For instance, the chuck plates 233a and 233b can rotate by an angle of 360°.

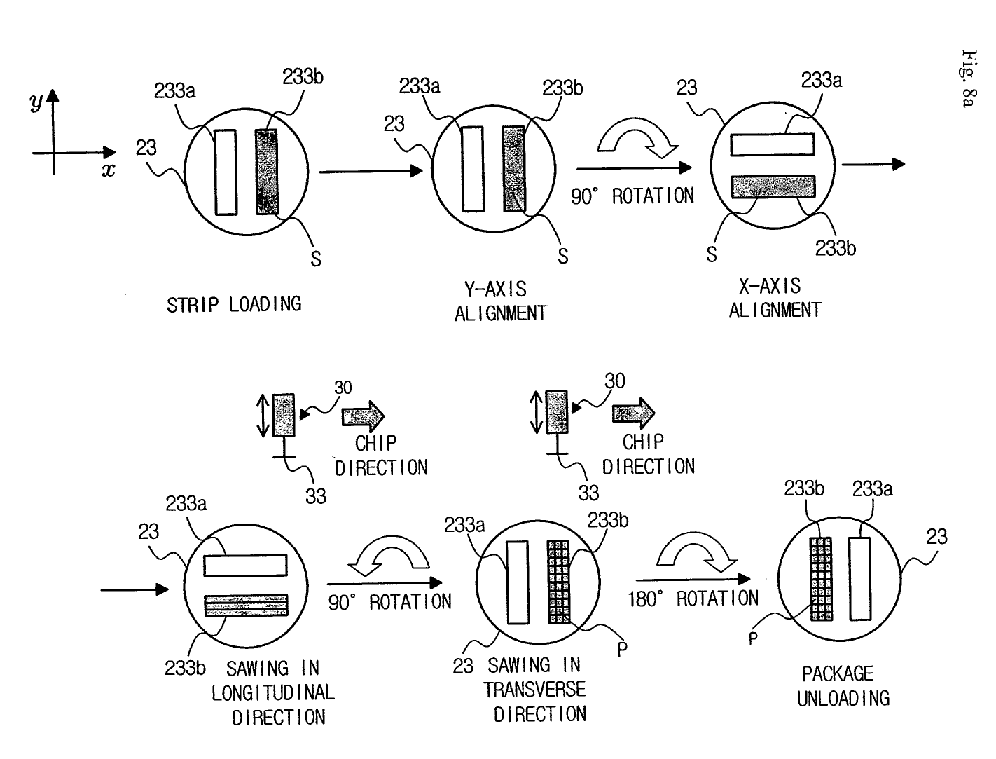

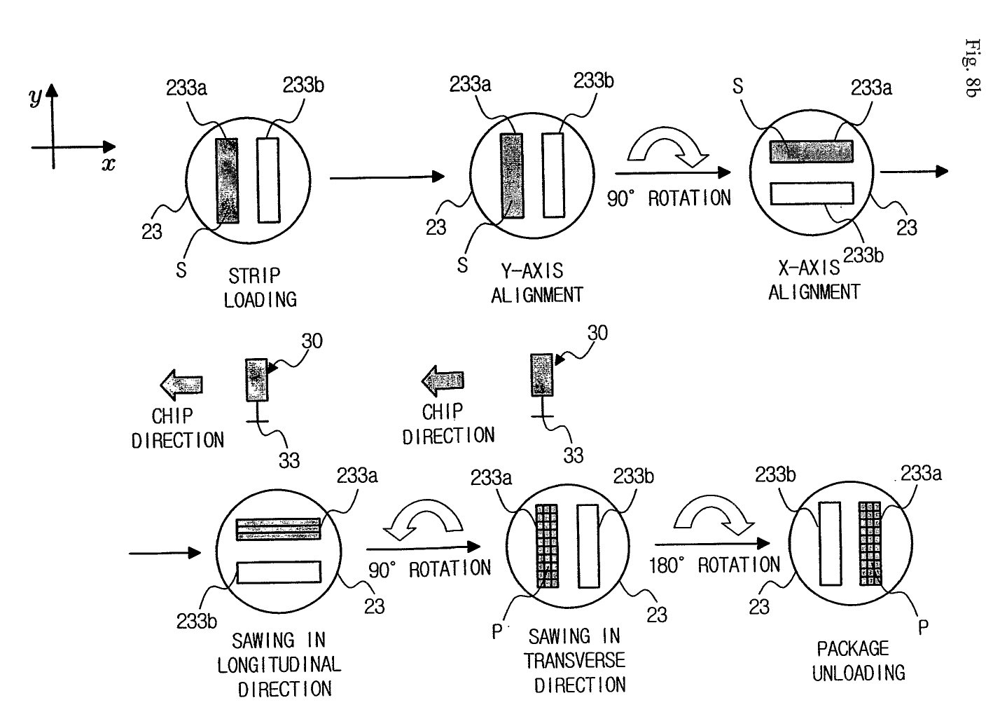

FIG. 8a is a view illustrating another control procedure for the sawing apparatus for manufacturing the semiconductor package according to the first embodiment of the present invention.

Similar to the control procedure shown in FIG. 7a, the control procedure shown in FIG. 8a includes the steps of loading the strip S, aligning the strip S, sawing the strip S and unloading the package P.

First, the strip S is loaded on the chuck plate 233b positioned on the right side of the chuck plate 233a. Then, the X and Y-axis alignment is performed with respect to the strip S loaded on the chuck plate 233b. To this end, the strip S loaded on the chuck plate 233b is horizontally transferred to a position corresponding to a vision inspection device and then the Y-axis alignment is performed with respect to the strip S loaded on the chuck plate 233b. After that, the strip S is rotated in the clockwise direction by an angle of 90° such that the X-axis alignment can be performed with respect to the strip S.

After that, the strip S aligned on the chuck plate 233b is sawn into individual packages P. First, the strip S is sawn in the longitudinal direction along the width thereof at regular intervals and then the strip S is sawn in the transverse direction along the length thereof at regular intervals by rotating the strip S in the counterclockwise direction by an angle of 90°.

In order to prevent the chuck plate 233a having no strip S loaded thereon from being contaminated by chips, the chips generated during the sawing process are preferably guided into a predetermined direction (chip direction shown in FIG. 8a) other than the direction toward the chuck plate 233a. That is, different from FIGS. 7a and 7b, the sawing blade 33 of the sawing machine 30 for sawing the strip S is rotated in the counterclockwise direction when viewed in the Y-axis direction, thereby allowing the chips to be guided in the right direction in FIG. 8a. Preferably, the sawing apparatus is designed such that a handler system including the cleaning unit 40 can be prevented from being contaminated by the chips generated during the sawing process.

After the sawing process has been finished, the packages P are rotated in the clockwise direction by an angle of 180° and then horizontally moved into the package unloading position. Thus, the individual packages P are unloaded from the chuck plate 233b and a new strip S is loaded onto the chuck plate 233a, simultaneously. Although FIG. 8a illustrates the packages P rotated in the clockwise direction by an angle of 180°, it is also possible to rotate the packages P in the counterclockwise direction by an angle of 180°.

Accordingly, similar to the control procedure shown in FIG. 7a, the chuck plate 233b is maintained in a position rotated from the initial position of the chuck plate by an angle of 180°, so that the packages P can be unloaded from the chuck plate 233b and the new strip S can be loaded onto the chuck plate 233a, simultaneously.

FIG. 8b shows a control procedure, in which the loading position of the strip S is different from that of the control procedure shown in FIG. 8a. That is, according to FIG. 8b, the strip S is loaded onto the chuck plate 233a other than the chuck plate 233b. This can be achieved by interchanging the positions of the strip picker and the package picker.

The control procedure shown in FIG. 8b is substantially similar to the control procedure shown in FIG. 8a except for the position of the strip S.

Since the strip S shown in FIG. 8b is loaded onto the chuck plate 233a, other than the chuck plate 233b as shown in FIG. 8a, the chips can be guided into the left direction (chip direction) in FIG. 8b even if the rotational direction of the sawing blade 33 is not changed, so that the handler system can be prevented from being contaminated by the chips.

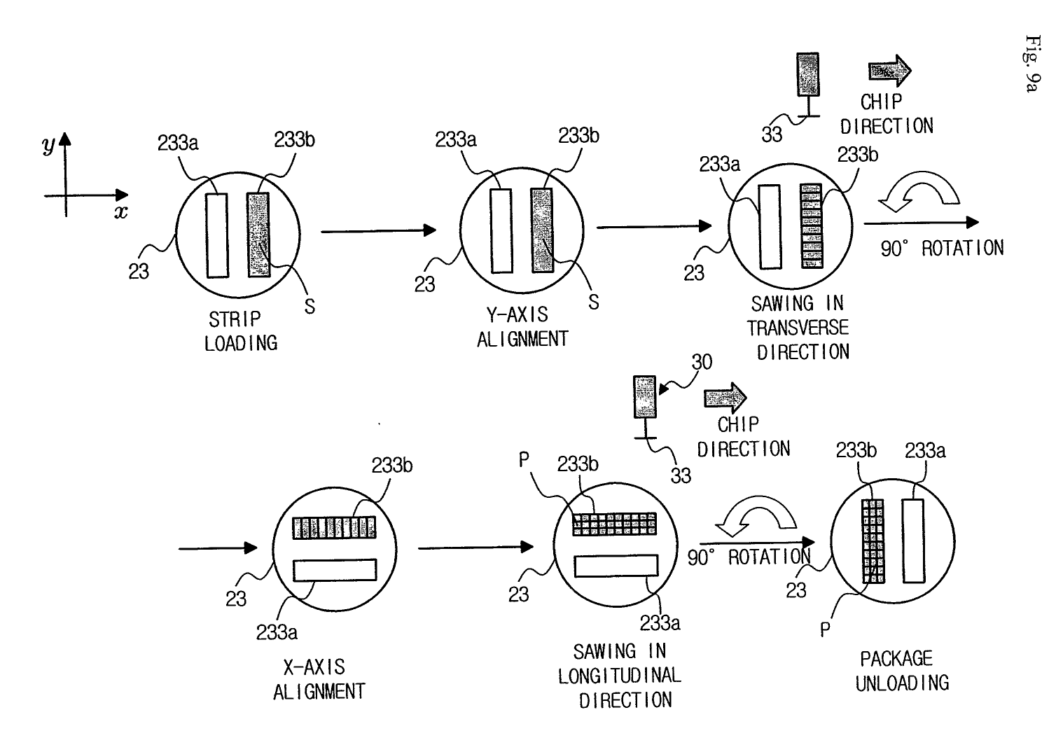

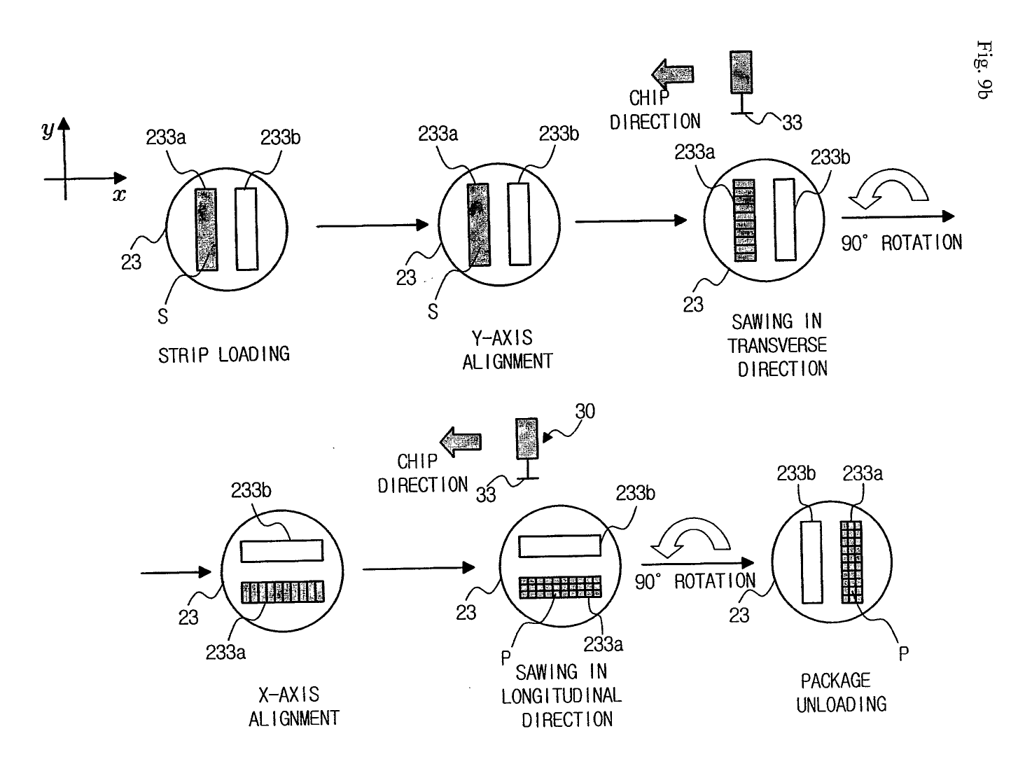

FIG. 9a is a view illustrating still another control procedure for the sawing apparatus for manufacturing the semiconductor package according to the first embodiment of the present invention.

Similar to the control procedure shown in FIG. 7a, the control procedure shown in FIG. 9a includes the steps of loading the strip S, aligning the strip S, sawing the strip S and unloading the package P. However, according to the control procedure shown in FIG. 9a, the step of aligning the strip S is incorporated with the step of sawing the strip S.

First, the strip S is loaded on the chuck plate 233b positioned on the right side of the chuck plate 233a.

Then, the strip S loaded on the chuck plate 233b is horizontally transferred to a vision inspection position and then the Y-axis alignment is performed with respect to the strip S. After that, the strip S aligned on the chuck plate 233b is sawn in the transverse direction along the length thereof at regular intervals.

At this time, in order to prevent the chuck plate 233a having no strip S loaded thereon from being contaminated by chips generated during the sawing process, the sawing blade 33 of the sawing machine 30 for sawing the strip S is preferably rotated in the counterclockwise direction when viewed in the Y-axis direction, thereby allowing the chips to be guided in the right direction in FIG. 9a. Preferably, the sawing apparatus is designed such that a handler system including the cleaning unit 40 can be prevented from being contaminated by the chips generated during the sawing process.

After that, the strip S is rotated in the counterclockwise direction by an angle of 90° such that the X-axis alignment can be performed with respect to the strip S. Then, the strip S is sawn in the longitudinal direction along the width thereof at regular intervals.

After the sawing process has been finished, the packages P are rotated in the counterclockwise direction by an angle of 90° and then horizontally moved into the package unloading position. Thus, the individual packages P are unloaded from the chuck plate 233b and a new strip S is loaded onto the chuck plate 233a, simultaneously.

Accordingly, similar to the control procedure shown in FIG. 7a, the chuck plate 233b is maintained in a position rotated from the initial position of the chuck plate by an angle of 180°, so that the packages P can be unloaded from the chuck plate 233b and the new strip S can be loaded onto the chuck plate 233a, simultaneously.

FIG. 9b shows a control procedure, in which the loading position of the strip S is different from that of the control procedure shown in FIG. 9a. That is, according to FIG. 9b, the strip S is loaded onto the chuck plate 233a other than the chuck plate 233b. This can be achieved by interchanging the positions of the strip picker and the package picker.

The control procedure shown in FIG. 9b is substantially similar to the control procedure shown in FIG. 9a except for the position of the strip S.

Since the strip S shown in FIG. 9b is loaded onto the chuck plate 233a, other than the chuck plate 233b as shown in FIG. 9a, the chips can be guided into the left direction (chip direction) in FIG. 9b even if the rotational direction of the sawing blade 33 is not changed, so that the handler system can be prevented from being contaminated by the chips.

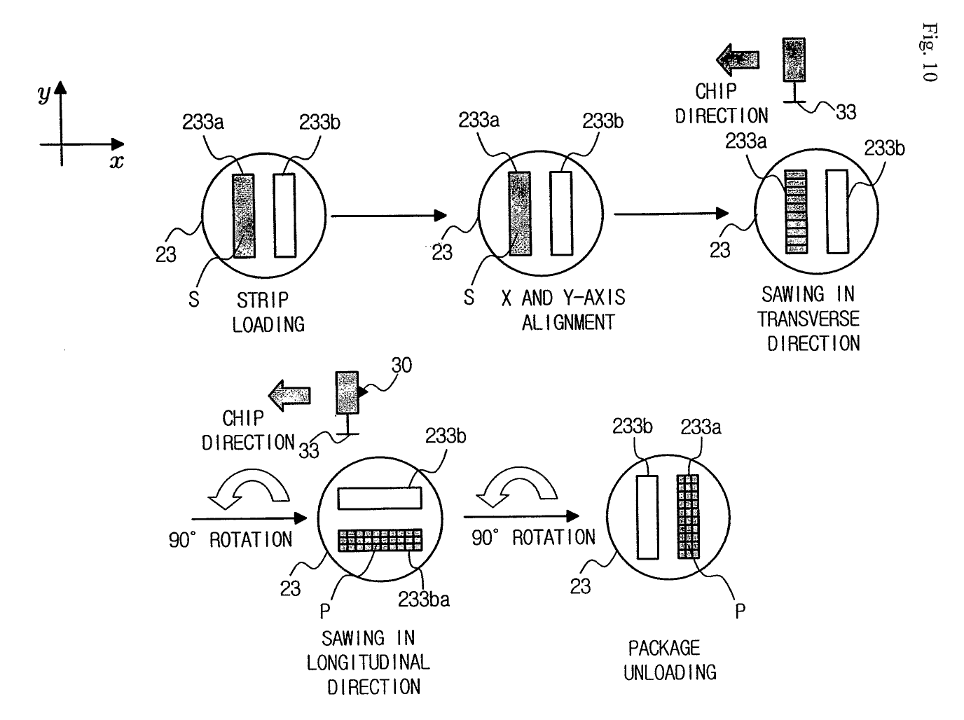

FIG. 10 is a view illustrating still yet another control procedure for the sawing apparatus for manufacturing the semiconductor package according to the first embodiment of the present invention.

According to the control procedure shown in FIG. 10, the X and Y-axis alignment for the strip S is achieved through the vision inspection without rotating the strip S loaded on the chuck plate 233b.

Then, the strip S is sawn in the transverse direction along the length thereof at regular intervals. After that, the strip S is rotated in the counterclockwise direction by an angle of 90°, and then the strip S is sawn in the longitudinal direction along the width thereof at regular intervals.

After the sawing process has been finished, the packages P are rotated in the counterclockwise direction by an angle of 90° and then horizontally moved into the package unloading position. Thus, the individual packages P are unloaded from the chuck plate 233b and a new strip S is loaded onto the chuck plate 233a, simultaneously.

In order to perform the X and Y-axis alignment for the strip S without rotating the strip S as shown in FIG. 10, a special vision inspection device is required. That is, the vision inspection device must perform the X and Y-axis alignment for the strip S while performing the vision inspection one time in the X-axis direction, the Y-axis direction or the diagonal direction of the strip S.

In the meantime, different from FIG. 10, it is also possible to rotate the strip S in the clockwise direction by an angle of 90°.

Hereinafter, the description will be made in relation to a system disclosed in Korean Patent Application No 10-2003-35020, which has been filed by applicant of the present invention, by applying the chuck table according to the present invention to the system. The system disclosed in Korean Patent Application No 10-2003-35020 has an advantage that the components thereof are aligned corresponding to process steps. However, since the system is provided with a single table, the strip cannot be loaded onto the chuck table until the package picker picks up the package from the chuck table. Thus, the above system may present problems occurring in the prior art.

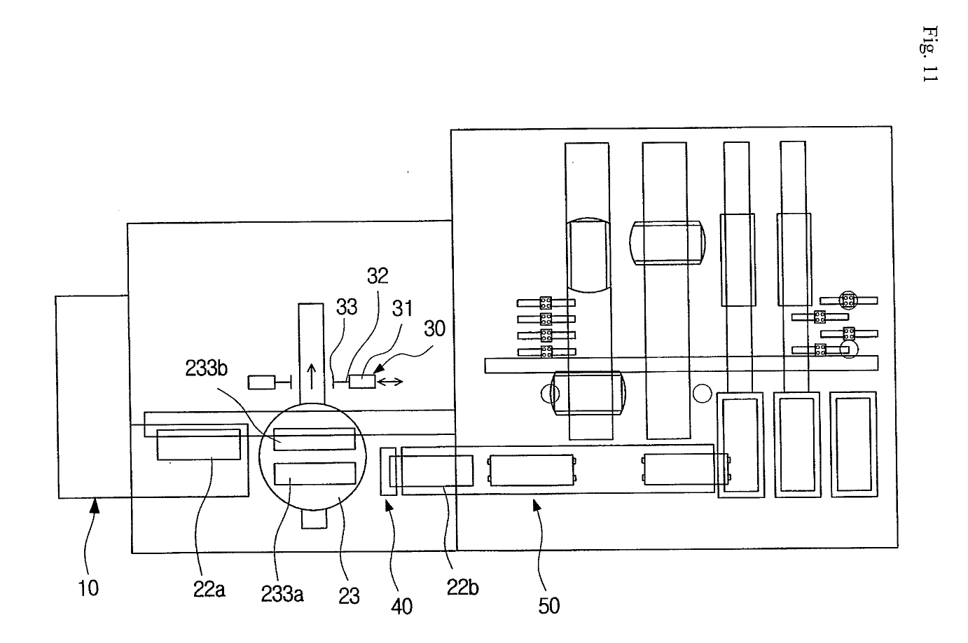

FIG. 11 is a plan view illustrating a sawing apparatus for manufacturing a semiconductor package according to a second embodiment of the present invention.

As shown in FIG. 11, similar to the sawing apparatus according to the first embodiment of the present invention, the sawing apparatus for manufacturing the semiconductor package according to the second embodiment of the present invention includes a chuck table 23 equipped with two chuck plates 233a and 233b, a sawing machine 30, a strip picker 22a and a package picker 22b.

However, different from the first embodiment of the present invention, an on-loader unit 10 is coupled to one side of the sawing apparatus. In addition, the strip picker 22a for loading the strip S onto the chuck table 23 is separated from the package picker 22b for moving packages P into a cleaning unit. When viewed from a plan view, the package picker 22b is positioned at a front portion of the system as compared with the strip picker 22a. In the meantime, a ceiling member of the system extends forward of the system and a guide rail is installed below the ceiling member so as to mount the strip picker 22a and the package picker 22b on the guide rail. In addition, the chuck table 23 can horizontally move in the Y-axis direction. The sawing machine 30 includes a pair of sawing blades 33 symmetrically aligned in the X-axis direction and moves in the X-axis direction to perform sawing work with respect to the strip S.

Therefore, in the sawing apparatus according to the second embodiment of the present invention, the strip picker 22a is installed separately from the package picker 22b to perform loading work for the strip S and unloading work for the packages, respectively, so that the strip S and the packages P can be effectively loaded/unloaded onto/from the chuck plate. In addition, since the on-loader unit 10 is directly coupled to one side of the sawing apparatus, the alignment of the system can be simplified, thereby facilitating the processes and improving workability of the system.

Hereinafter, a method for controlling the sawing apparatus for manufacturing the semiconductor package according to the second embodiment of the present invention will be described with reference to accompanying drawings.

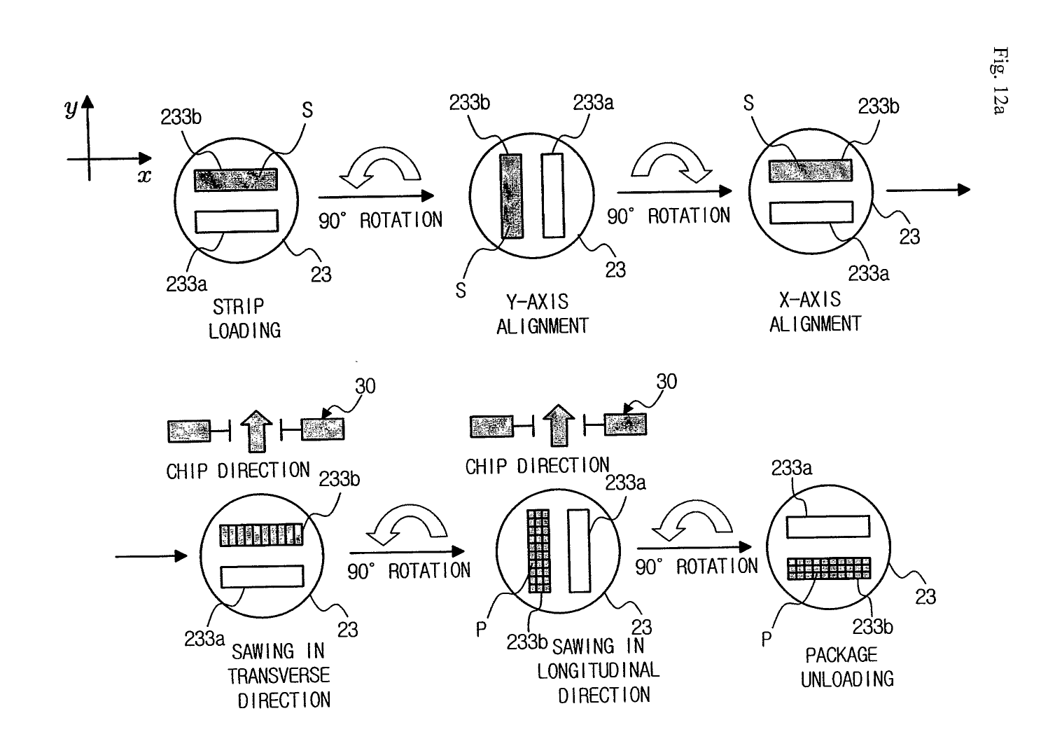

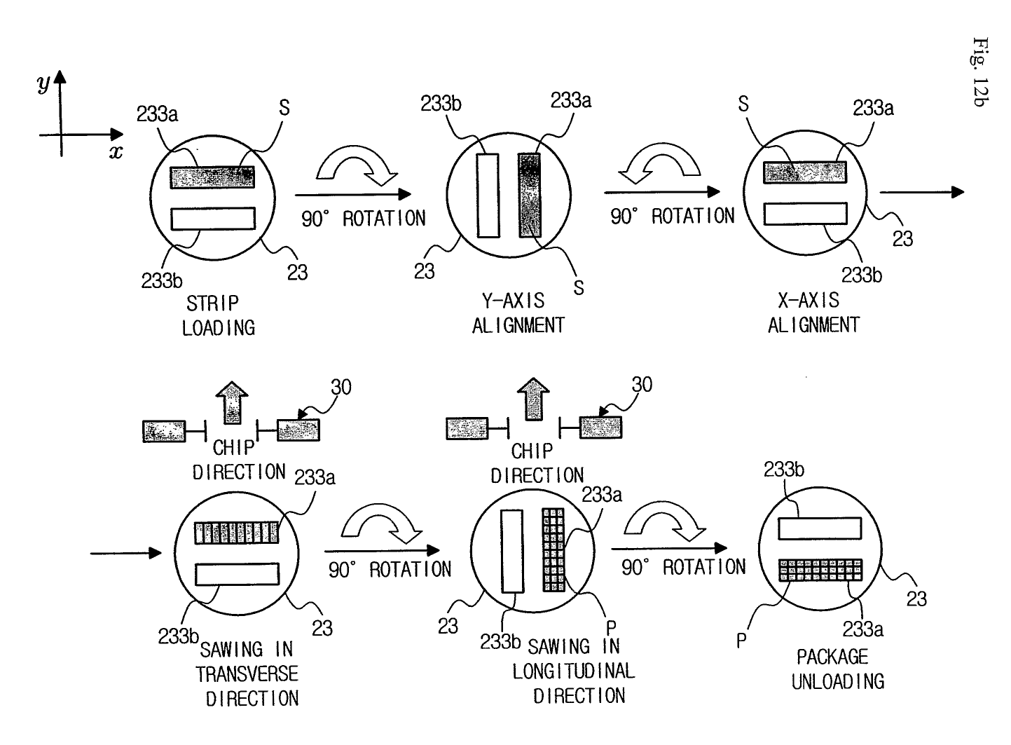

FIGS. 12a to 15 are views illustrating a control procedure for the sawing apparatus for manufacturing the semiconductor package according to the second embodiment of the present invention.

Similar to the control procedure according to the first embodiment of the present invention, the control procedure according to the second embodiment of the present invention includes the steps of loading the strip S, aligning the strip S, sawing the strip S and unloading the package P.

That is, the control procedure according to second embodiment of the present invention is identical to the control procedure according to the first embodiment of the present invention except that the strip S is parallel-loaded on the chuck table in the X-axis direction, the strip S is sawn by the relative movement between the sawing machine 30 moving in the X-axis direction and the chuck plates 233a and 233b moving in the Y-axis direction, and loading/unloading work for the strip S and the packages P. That is, the rotational direction and rotating angle of the chuck plates 233a and 233b may be variously selected if the chuck plates 233a and 233b can be maintained in a predetermined position rotated from the initial position (strip loading position) by an angle of 180° when the package P is unloaded from the chuck plate after the sawing process has been finished.

The control procedure shown in FIG. 12 is basically identical to the control procedure shown in FIG. 7a.

First, the strip S is loaded on the chuck plate 233b, which is positioned above the chuck plate 233a when viewed from the plan view. To this end, the strip picker head 221 picks up the strip S introduced into the sawing apparatus and moves towards an upper portion of the chuck plate 233b to load the strip S onto the chuck plate 233b.

Then, the X and Y-axis alignment is performed with respect to the strip S loaded on the chuck plate 233b. To this end, the strip S loaded on the chuck plate 233b is horizontally transferred to the vision inspection device in the Y-axis direction. In this state, the Y-axis alignment is performed with respect to the strip S by rotating the strip S in the counterclockwise direction by an angle of 90° and then the X-axis alignment is performed with respect to the strip S by rotating the strip S in the clockwise direction by an angle of 90°.

After that, the strip S aligned on the chuck plate 233b is sawn into individual packages P. First, the strip S is sawn in the transverse direction along the length thereof at regular intervals and then the strip S is sawn in the longitudinal direction along the width thereof at regular intervals by rotating the strip S in the clockwise direction.

In detail, the sawing blade 33 of the sawing machine 30 being rotated above the strip S moves down toward the strip S and the chuck plate 233b having the strip S loaded thereon is horizontally moved in the Y-axis direction by means of the chuck table 23, so that the strip S is sawn in the transverse and longitudinal directions thereof. At this time, the sawing machine 30 moves from a front portion to a rear portion of the strip S in the X-axis direction with a predetermined time interval, thereby sawing the strip S at regular intervals.

In order to prevent the chuck plate 233a having no strip S loaded thereon from being contaminated by chips generated during the sawing process, the chips are preferably guided into a predetermined direction (chip direction shown in FIG. 12a) other than the direction toward the chuck plate 233a. That is, the sawing blade 33 of the sawing machine 30 for sawing the strip S is rotated in the clockwise direction when viewed in the X-axis direction, thereby allowing the chips generated during the sawing process to be guided in the rear direction in FIG. 12a.

After the sawing process has been finished, the packages P are rotated in the clockwise direction by an angle of 90° and then horizontally moved into the package unloading position. Thus, the individual packages P are unloaded from the chuck plate 233b and a new strip S is loaded onto the chuck plate 233a, simultaneously.

At this time, the chuck plate 233b is located below the chuck plate 233a and maintained in a position rotated from the initial position of the chuck plate by an angle of 180°, so that the packages P can be unloaded from the chuck plate 233b and the new strip S can be loaded on the chuck plate 233a, simultaneously.

In the meantime, referring to FIG. 12b, the strip S can be loaded onto the chuck plate 233a other than the chuck plate 233b on which the strip S is loaded in FIG. 12a. That is, the strip S is alternately loaded on upper surfaces of the chuck plates 233a and 233b.

The control procedure shown in FIG. 12b is substantially similar to the control procedure shown in FIG. 12a except for the rotational direction of the chuck plates 233a and 233b. Thus, detailed description thereof will be omitted below.

Since the rotational direction of the strip S shown in FIG. 12b is reversed with respect to the rotational direction of the strip S shown in FIG. 12a, the rotating angle of the chuck plates 233a and 233b is limited within an angle of 180°. Thus, the tangling of cables or vacuum lines, which may occur when the chuck plates 233a and 233b excessively rotate, can be prevented. However, in the same manner as the first embodiment of the present invention, if there is no problem derived from the tangling of the cables or vacuum lines, it is not necessary to limit the rotating angle of the chuck plates 233a and 233b within an angle of 180°.

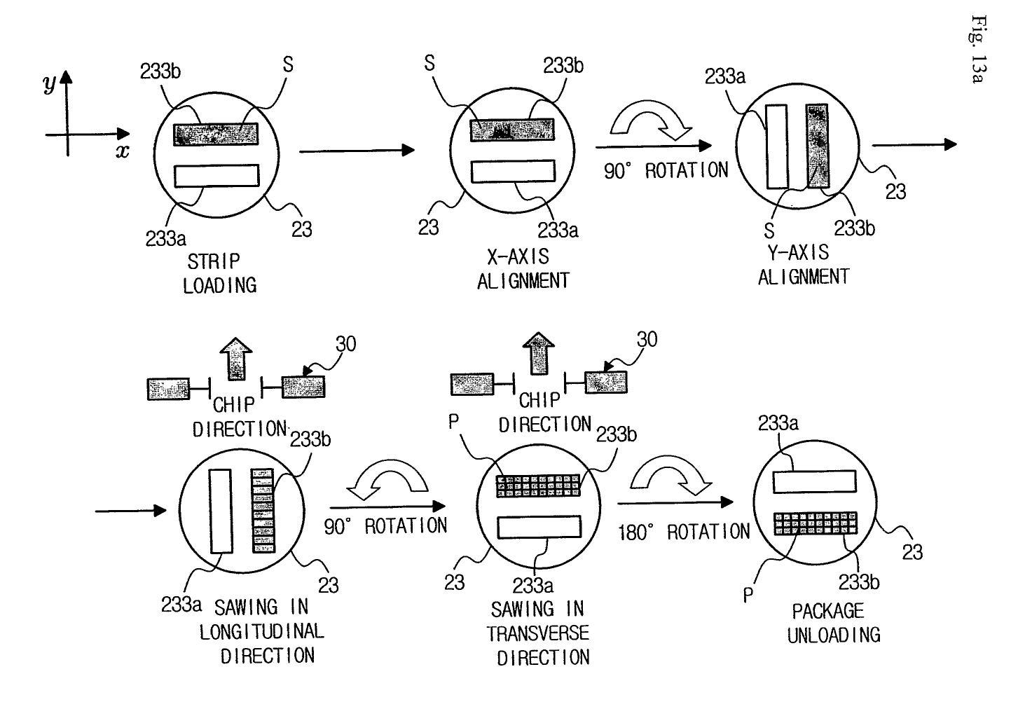

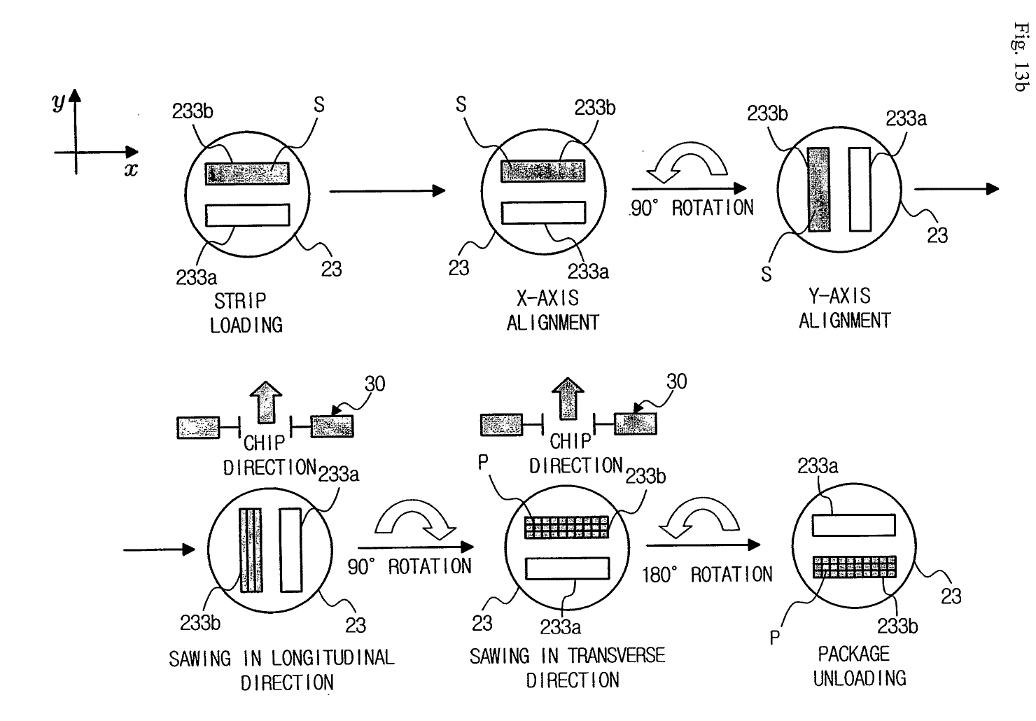

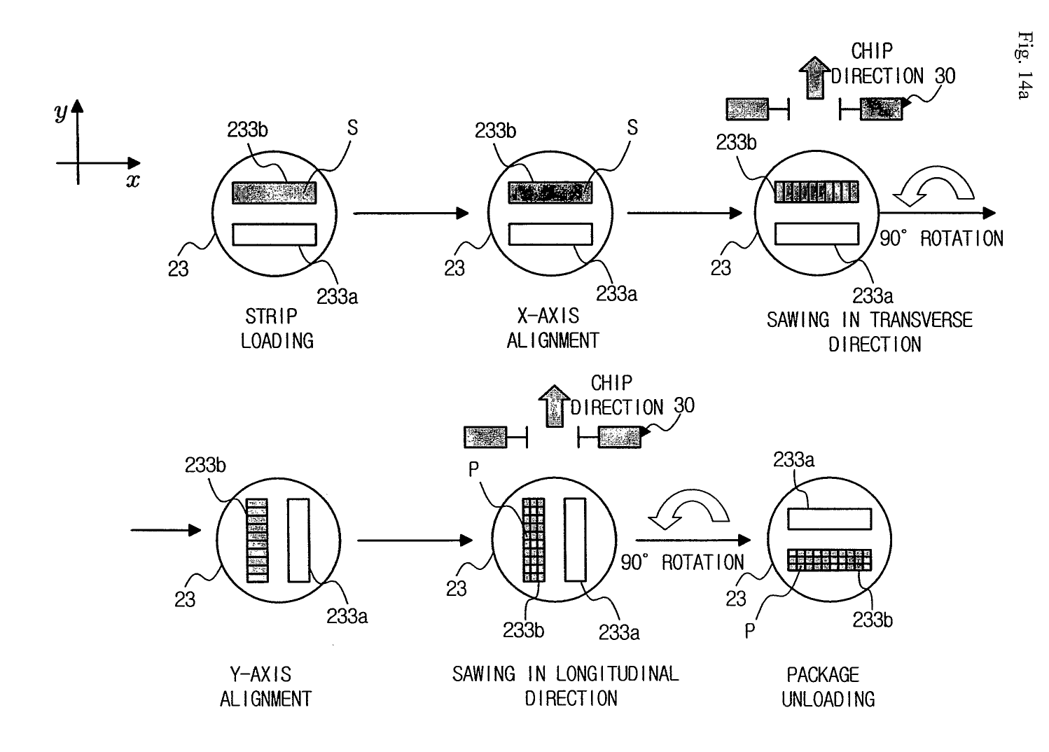

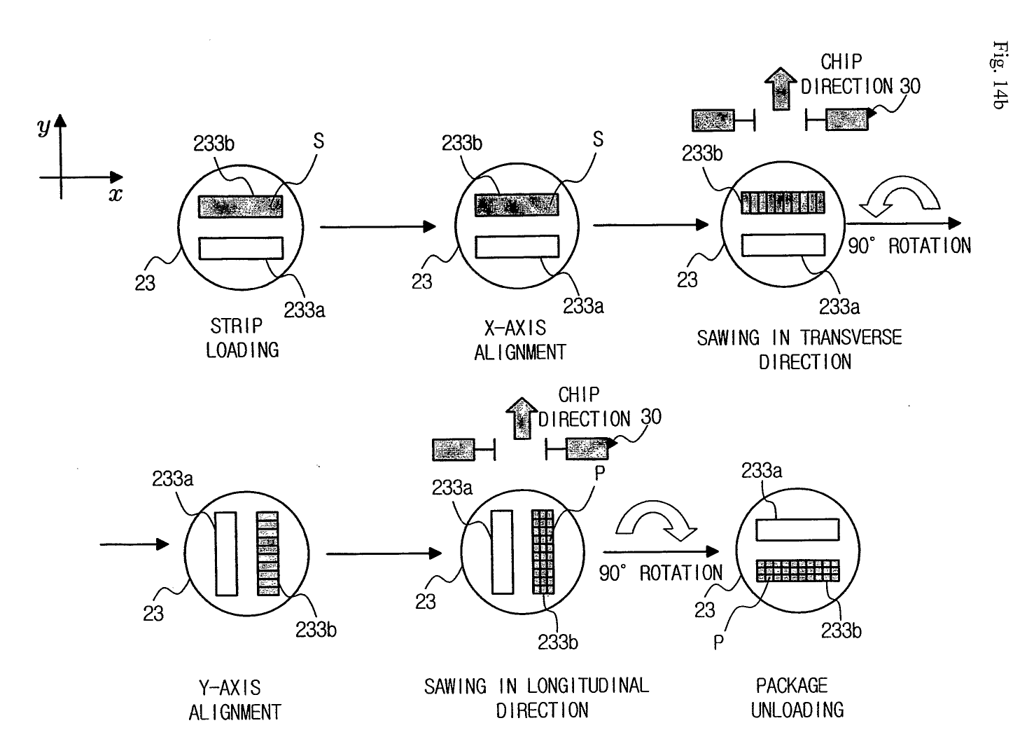

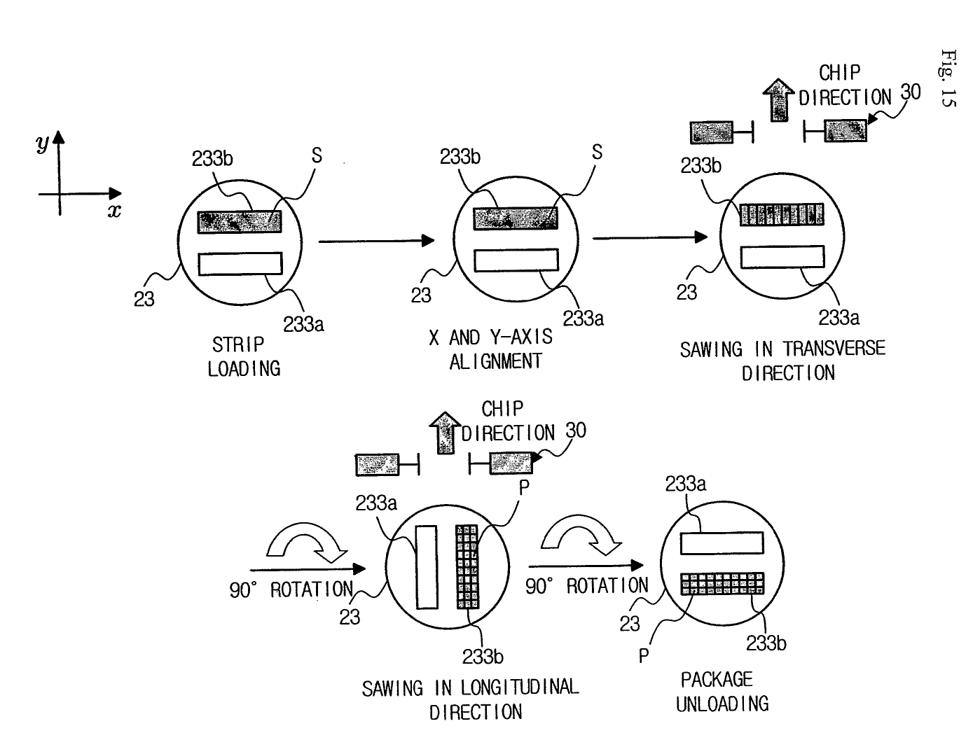

FIGS. 13a and 13b illustrate the control procedure obtained by combining the control procedures shown in FIGS. 12a and 8a and the control procedures shown in FIGS. 12b and 8b, respectively. FIGS. 14a and 14b illustrate the control procedure obtained by combining the control procedures shown in FIGS. 12a and 9a and the control procedures shown in FIGS. 12b and 9b, respectively. In addition, FIG. 15 illustrates the control procedure obtained by combining the control procedures shown in FIGS. 14b and 10.

Meanwhile, it should be noted that FIGS. 7a, 7b, 12a and 12b show a whole cycle of the present invention (that is, the strip is alternately loaded on the chuck plates of the chuck table) and FIGS. 8a, 8b, 9a, 9b, 10, 13a, 13b, 14a, 14b and 15 only show the step of loading the strip onto the chuck table, other than the whole cycle of the present invention. The whole cycle of the present invention, in which the strip is alternately loaded on the chuck plates of the chuck table, can be easily understood with reference to FIGS. 7b and 12b.

The whole cycle and the step of loading the strip onto the chuck table can be understood through combinations of the above-described control procedures, so they will not be further described below.

While this invention has been described in connection with what is presently considered to be the most practical and preferred embodiment, it is to be understood that the invention is not limited to the disclosed embodiment and the drawings, but, on the contrary, it is intended to cover various modifications and variations within the spirit and scope of the appended claims.

### INDUSTRIAL APPLICABILITY

As can be seen from the foregoing, according to the sawing apparatus for manufacturing the semiconductor package and the method for controlling the same of the present invention, two chuck plates are provided on the chuck table so that loading work for the strip is performed simultaneously with unloading work for the packages when performing the sawing process to fabricate the semiconductor package, thereby improving productivity of the semiconductor packages.

In addition, chips generated during the sawing process for the strip may not be directed toward the chuck plate having no strip loaded thereon, so that the chuck plate can be prevented from being contaminated.

Furthermore, the rotating angle of the chuck plates is limited within an angle of 180°, so that it is not necessary to rotate the chuck plate with wide angles.

In addition, according to the present invention, the on-loader unit is directly coupled to one side of the sawing apparatus and the strip picker for loading the strip is separated from the package picker for unloading the packages. Thus, the loading work for the strip and the unloading work for the packages can be effectively performed. The present invention simplifies the alignment of the system so that the processes can be facilitated, improving productivity of the system per unit time.

1. A sawing apparatus for manufacturing a semiconductor package, the sawing apparatus comprising:
a chuck table base;
a chuck table installed on the chuck table base such that the chuck table horizontally moves on the chuck table base;
two chuck plates rotatably installed on the chuck table such that a strip is loaded on upper surfaces of the chuck plates by turns;
a sawing machine for dividing the strip loaded on the chuck plate into individual packages by performing a relative movement with respect to the chuck table; and
a strip/package picker for loading the strip onto the chuck plates and unloading the packages from the chuck plates, simultaneously.

2. The sawing apparatus as claimed in claim 1, wherein the chuck table is rotated from an initial position thereof by an angle of 180° when a sawing process has been finished in such a manner that a new strip is loaded onto the chuck plates of the chuck table and the packages are unloaded from the chuck table by means of the strip/package picker, simultaneously.

3. The sawing apparatus as claimed in claim 2, wherein the chuck table is alternately rotated in forward and reverse directions by an angle of 180° so as to prevent cables from being entangled.

4. The sawing apparatus as claimed in claim 2, wherein a rotational direction and a rotating angle of the chuck table is controlled such that the chuck table is positioned within an angle of 180° from the initial position thereof when the strip is aligned.

5. The sawing apparatus as claimed in claim 1, wherein the sawing machine includes a spindle which is rotated as a predetermined power is applied thereto and a sawing blade installed at one end of the spindle so as to divide the strip into individual packages, a rotational direction of the spindle being controlled such that chips generated during a sawing process for the strip are not directed toward the chuck plate having no strip loaded thereon.

6. A method of controlling a sawing apparatus for manufacturing a semiconductor package and including two chuck plates, the method comprising the steps of:
i) loading a strip on a first chuck plate of two chuck plates;
ii) aligning the strip loaded on the first chuck plate;
iii) sawing the strip loaded on the first chuck plate into individual packages; and
iv) unloading the packages by rotating the first chuck plate from an initial position thereof by an angle of 180° and loading a new strip onto a second chuck plate of two chuck plates, simultaneously.

7. The method as claimed in claim 6, wherein, in step ii), a rotational direction and a rotating angle of a chuck table is controlled such that the chuck table is positioned within an angle of 180° from an initial position thereof.

8. The method as claimed in claim 7, wherein chips generated during a sawing process for the strip are directed in a predetermined direction without being directed toward the second chuck plate having no strip loaded thereon.

9. The method as claimed in claim 7, wherein, after step iii), the packages aligned in a position rotated from the initial position of the chuck table by an angle of 180° are horizontally transferred to a package unloading position.

10. The method as claimed in any one of claims 6 to 9, wherein steps ii) to iv) are repeated after step iv) has been finished, in which a rotational direction of the strip is reversed in each step.

11. A sawing apparatus for manufacturing a semiconductor package, the sawing apparatus comprising:
a chuck table base;
a chuck table installed on the chuck table base such that the chuck table horizontally moves in a Y-axis direction on the chuck table base;
two chuck plates rotatably installed on the chuck table such that a strip is loaded on upper surfaces of the chuck plates by turns;
a sawing machine for dividing the strip loaded on the chuck plate into individual packages by performing a relative movement with respect to the chuck table;
a strip picker for loading the strip onto the chuck plate while moving in an X-axis direction; and
a package picker for unloading the packages from the chuck plate while moving in the X-axis direction in parallel to the strip picker when the strip picker loads the strip onto the chuck plate.
